(19) United States
(12) Patent Application Publication
(10) Pub. No.: US 2024/0105625 A1
(43) Pub. Date: Mar. 28, 2024

(54) OPEN CAVITY INTERCONNECTS FOR MIB CONNECTIONS

(71) Applicant: Intel Corporation, Santa Clara, CA (US)

(72) Inventors: Brandon C. Marin, Gilbert, AZ (US); Kristof Darmawikarta, Chandler, AZ (US); Benjamin Duong, Phoenix, AZ (US); Srinivas Venkata Ramanuja Pietambaram, Chandler, AZ (US); Gang Duan, Chandler, AZ (US)

(21) Appl. No.: 17/953,511

(22) Filed: Sep. 27, 2022

(51) Int. Cl. H01L 23/538; H01L 21/48; H01L 23/498; H01L 25/065

(52) U.S. Cl. CPC H01L 23/5381; H01L 21/486; H01L 23/49838; H01L 23/49894; H01L 23/5386; H01L 25/0655; H01L 24/17

(57) ABSTRACT

Disclosed herein are microelectronics package architectures utilizing open cavity interconnects for multi-die interconnect bridges and methods of manufacturing the same. The microelectronics packages may include a substrate, a first die, a solder resist layer, a first pad, and a bridge. The substrate may have a substrate surface. The solder resist layer may be connected to the substrate and may define an opening. The first pad may protrude from the substrate surface. The bridge may be located at least partially within the opening and in between the first die and the substrate. The bridge may include a first via that forms a first electrical pathway from the first pad to the first die.

### FIELD OF THE DISCLOSURE

The present subject matter relates to microelectronics packages. More specifically, the present disclosure relates to open cavity interconnects for multi-die interconnect bridges (MIB) connections and methods of manufacturing the same.

### BACKGROUND

Current 2.5 dimensional (2.5D) technologies have limitations in power delivery. There is currently no solution that permits through-silicon via (TSV) connection with the standard EMIB. Instead, current power delivery with EMIB is done by routing around the EMIB, which causes severe design restrictions. Currently, there is no high-volume manufacturing (HVM) solutions to connect an EMIB with TSVs (EMIB-T). Instead, power delivery with EMIBs is done by routing around the EMIBs. Routing around the EMIBs utilizes a great deal of space and causes severe design restrictions.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows a microelectronics package in accordance with at least one embodiment of this disclosure.

FIGS. 2A, 2B, 2C, and 2D show a process for manufacturing a microelectronics package in accordance with at least one example of this disclosure.

FIG. 3 shows system level diagram in accordance with at least one example of this disclosure.

### DETAILED DESCRIPTION

Heterogeneous integration may be used for band width (BW) scaling. The systems and methods disclosed herein provide for power delivery by providing through-silicon (Si) vias (TSVs). Silicon interposers may allow for silicon stacking above the front side resist (FSR) layer, which may make it easy to fuse TSVs and make vertical die-die interconnects. As disclosed herein, EMIB chiplets can be made with TSV's that permits TSV connection with the EMIB process flow. Thus, the systems and methods disclosed herein overcome power delivery problems of routing power around the EMIB.

The systems and methods disclosed herein include microelectronics packages that may include a substrate, a plurality of dies, a solder resist layer, pads, and a bridge. The substrate may have a substrate surface and the solder resist layer may be connected to the substrate and define an opening. The pads may protrude from the substrate surface. The bridge may be located at least partially within the opening and in between at least one of the dies and the substrate. The bridge may include a first via that forms a first electrical pathway from at least one of the pads to one of the plurality of dies.

Consistent with embodiments disclosed herein, the bridge is not embedded with the solder resist layer. A palladium seed may be located in between the solder resist layer and the substrate. Still consistent with embodiments disclosed herein, the bridge may be spaced a distance from the substrate surface. The distance may be from about 5 microns to about 10 microns.

One or more of the pads may be a metal defined pad. A layer that may include nickel, palladium, gold, or combination thereof may circumscribe a portion of one or more of the pads.

The bridge may have a thickness from about 35 microns to about 70 microns. The bridge may include a second via that forms a second electrical pathway from a second one of the plurality of pads to a second one of the plurality of dies.

The above discussion is intended to provide an overview of subject matter of the present patent application. It is not intended to provide an exclusive or exhaustive explanation. The description below is included to provide further information.

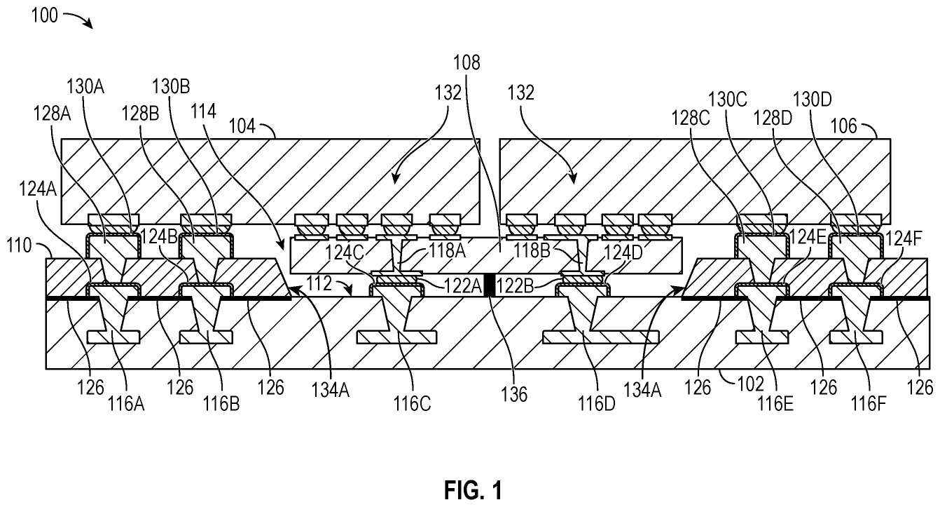

Turning now to the figures, FIG. 1 shows a microelectronics package 100 in accordance with at least one example of this disclosure. Microelectronics package 100 may include substrate 102, a first die 104, a second die 106, and a multi-interconnect bridge (MIB) 108. A solder resist layer 110 may be connected to a surface 112 of substrate 102. Solder resist layer 110 may define an opening 114. As disclosed herein, MIB 108 may be located at least partially within opening 114 and in between first die 104, second die 106, and substrate 102. MIB 108 may have a thickness from about 35 microns to about 70 microns, which is thinner than traditional bridges.

Pads 116 (labeled individually as pads 116A, 116B, 116C, 116D, 116E, and 116F) may protrude from surface 112. MIB 108 may comprise vias 118 (labeled individually as vias 118A and 118B). Vias 118 may form electrical pathways from pad 116C to first die 104 and pad 116D to second die 106. As a result, electrical power may be delivered to first and second dies 104, 106, without having to route around MIB 108.

As shown in FIG. 1, MIB 108 is not embedded with solder resist layer 110. Thus, MIB 108 allows for power to be delivered to first and second dies 104, 106, without traces or other electrical pathways that circumvent MIB 108. Since MIB 108 is not embedded within solder resist layer 110, MIB 108 may be referred to as an open cavity MIB.

One or more bumps 122 (labeled individually as bumps 122A and 122B) may be used to connect vias 118 to pads 116C and 116D. Because no underfill material is used to embed MIB 108, MIB 108, may be spaced a distance from surface 112. For example, MIB 108 may be spaced a distance of about 5 microns to about 10 microns above surface 112. This distance, and coupled with MIB 108 being in an open cavity may allow for air circulation around MIB 108 to enhance cooling of MIB 108, since solder resist materials are normally a thermal insulators.

Since there is no solder resist in opening 114, pads 116C and 116D may be metal defined pads. Pads 116C and 116D may also include plated layers 124A and 124B. Pads 116A, 116B, 116E, and 116F may be formed within solder resist layer 110 and thus may be mask defined pads. Pads 116A, 116B, 116E, and 116F may also include plated layers 124A, 124B, 124E, and 124F (collectively plated layers 124 along with plated layers 124C and 124D). Plated layers 124 may be a nickel, palladium, gold, or combination thereof layer that circumscribes a portion of pad 116C and 116D.

During manufacturing of microelectronics package 100, a palladium seed 126 located in between solder resist layer 110 and substrate 102. Palladium seed 126 may be applied to surface 112 and portions stripped away when opening 114 is formed as disclosed herein.

Pads 128 (labeled individually as pads 128A, 128B, 128C, and 128D) may be formed to provide power through solder resist layer 110. Because MIB 108 is not embedded within solder resist layer 110, pads 128 may have a height of about 30 μm, which is taller than traditional pads, which have heights ranging from about 5 μm to about 10 μm. Pads 128 may be metal defined pads and may include plated layers 130 (labeled individually as plated layers 130A, 130B, 130C, and 130D). Plated layers 130 may be a nickel, palladium, gold, or combination thereof layer that circumscribes a portion of pads 128. First and second dies 104 and 106 may be connected to MIB 108 and pads 128 (or plated layers 130) via bumps 132.

As disclosed herein, during forming of opening 114, sidewalls 134 (labeled individually as sidewalls 134A and 134B) may be formed. Formation of sidewalls 134 may result in sidewalls having a slanted profile as shown in FIG. 1, instead of a vertical profile.

A bonding agent 136 may be used to provide additional securement of MIB 108 to substrate 102. For example, an epoxy or thermal compound may be used to provide additional support for MIB 108 and further secure MIB 108 in a desired location. Thus, bonding agent 136 may work in conjunction with bumps 122 to secure MIB 108 and provide support during attachment of first and second dies 104 and 16. For example, bonding agent 136 may provide support to lessen the bending of MIB 108 as first and second dies 104 and 106 are pressed onto MIB 108.

The use of vias 118 allows for MIB chiplets, such as MIB 108, that allow for more efficient power delivery and better design flexibility. This leads to much better product performance and permits bandwidth scaling.

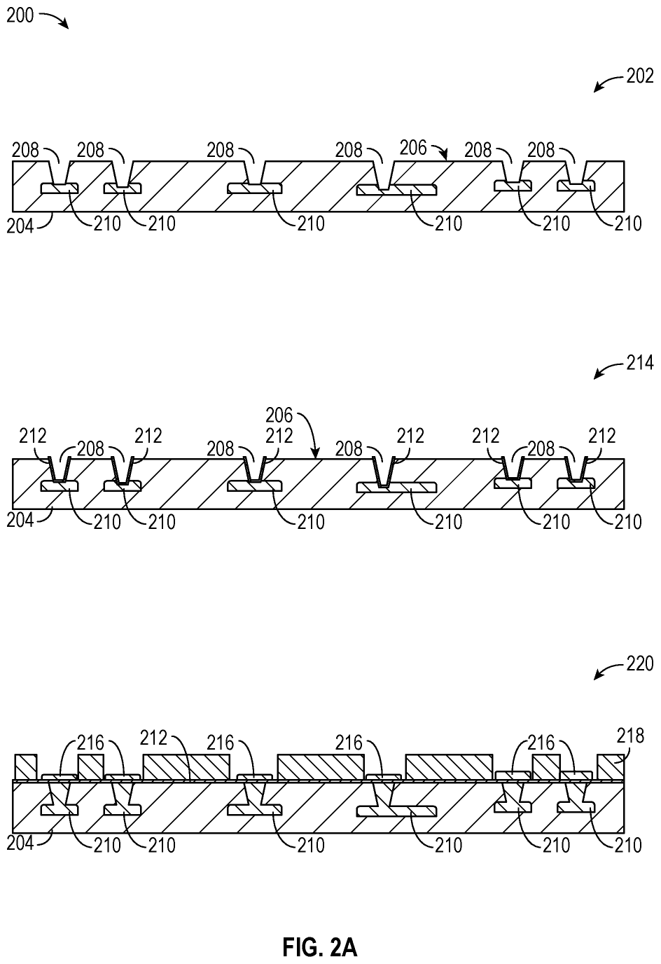

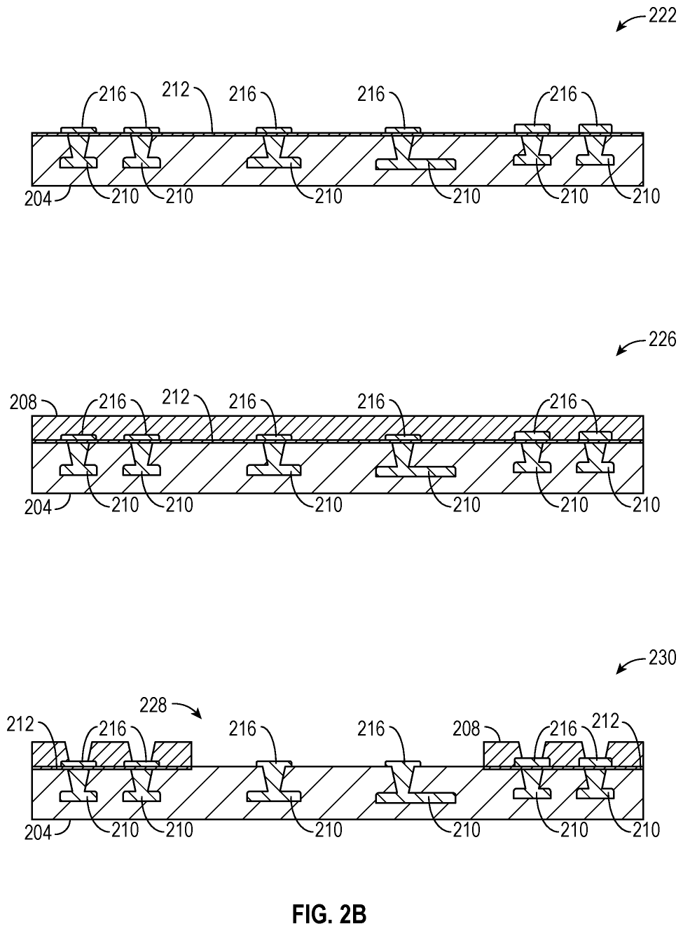

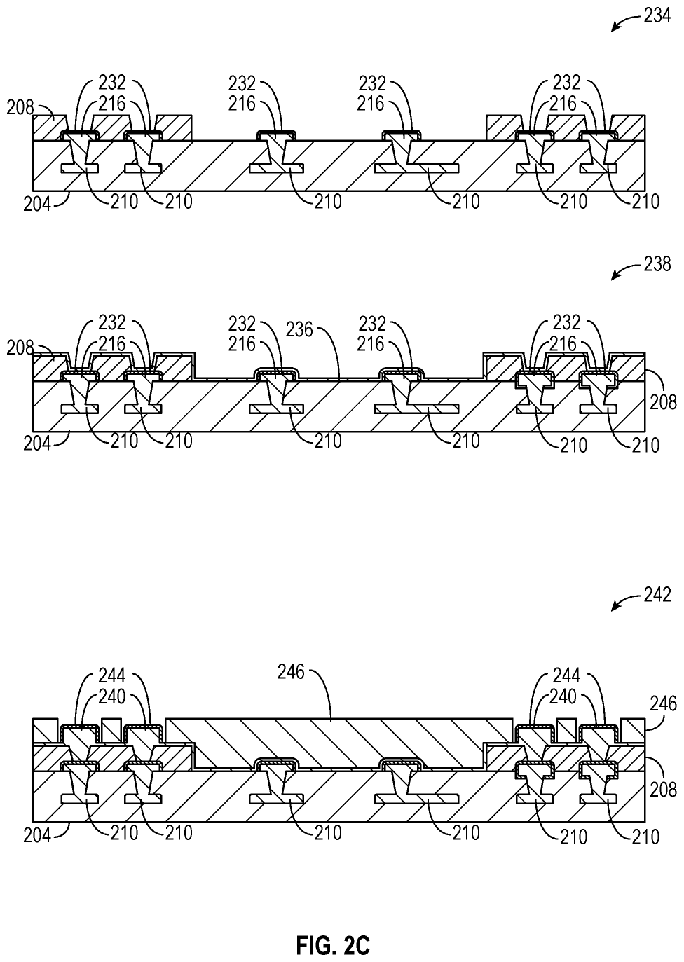

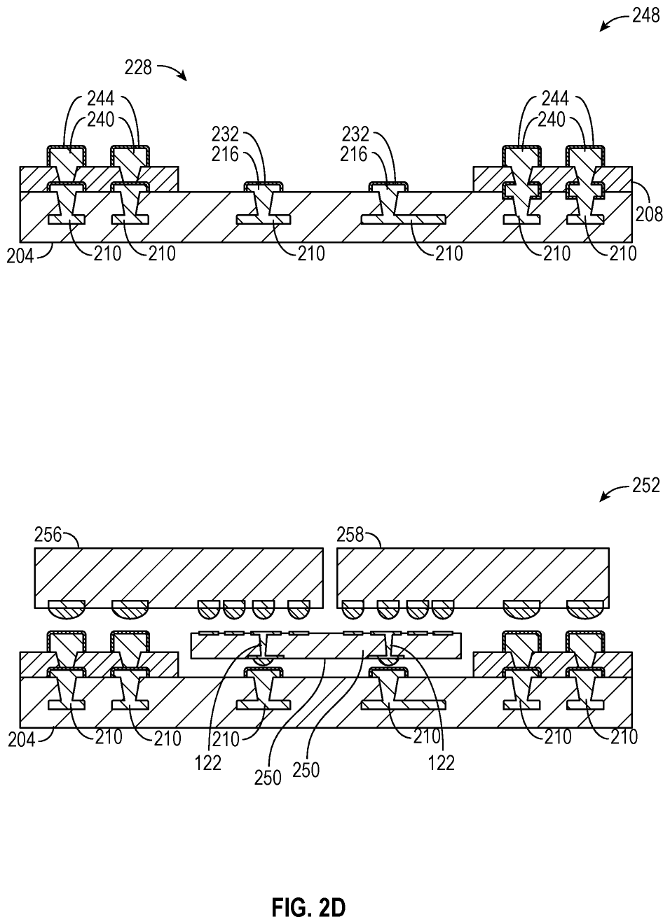

FIGS. 2A, 2B, 2C, and 2D shows a process flow 200 for manufacturing open cavity interconnects for multi-die interconnect bridges. Process flow 200 may begin at stage 202, where a substrate 204 including a substrate surface 206 is formed and one or more vias 210 are formed in substrate 204. Vias 210 may expose one or more traces 210.

After forming vias 210, a seed layer 212 may be formed (214). For example, seed layer 212 may be a palladium, electroless copper, or a combination thereof. Seed layer 212 may be formed by processes such as, but not limited to, deposition (physical or vapor), sputtering, etc.

After formation of seed layer 212, pads 216 and a resist layer 218 may be formed (220) on substrate surface 206. Resist layer 218 may be used to form pads 216. For example, pads 216 may be mask defined pads. Stated another way, resist layer 218 may be a mask that is used to define pads. Once pads 216 are formed, resist layer 218 may be removed (222). Removing resist layer 218 may include a flash etching process that leaves the palladium layer (seed layer 212) behind.

After removing resist layer 218, a solder resist layer 224 may be formed (226). Solder resist layer 224 may be formed by a solder resist lamination process. Once solder resist layer 224 is formed, a cavity 228 may be formed in solder resist layer 224 (230). When forming cavity 228, portions of seed layer 212 may be exposed and/or removed. For example, palladium located beneath solder resist layer where cavity 228 is formed may be exposed and/or removed during the formation of cavity 228.

Pads 216 may be plated with metallic layers 232 (234). Metallic layers 232 may include nickel, palladium, gold, silver, or any combination thereof. Metallic layers 232 may also be electroless metallic layers, such as a copper electroless layer. Once metallic layers 232 are formed, an electroless layer 236 may be formed (238). Electroless layer 236 may be a coper layer that may be used for forming one or more pillars 240 (242) for a first layer interconnect plating as disclosed herein. Pillars 240 may be plated with metallic layers 244 (242). Pillars 240 may also include pads that are metal defined or masked defined. For example, the pads of pillars 240 may be defined by a dry file resist layer 246. Metallic layers 244 may include nickel, palladium, gold, silver, or any combination thereof. Metallic layers 244 may also be electroless metallic layers, such as a copper electroless layer. Dry film resist layer 246 may be stripped away (248) after pillars 240 are formed. Portions of seed layers, such as the seed itself, may remain after removal of dry file resist layer 246.

With cavity 228 exposed, a bridge 250 may be installed within cavity (252). Installing bridge 250 may include attaching bridge 250 to the pads 210. Bridge 250 may be located at least partially within cavity 228 formed by resist layer 208. Bridge 250 may have through vias 254 that allow power to be transferred from pads 210 to first die 256 and second die 258 as disclosed herein.

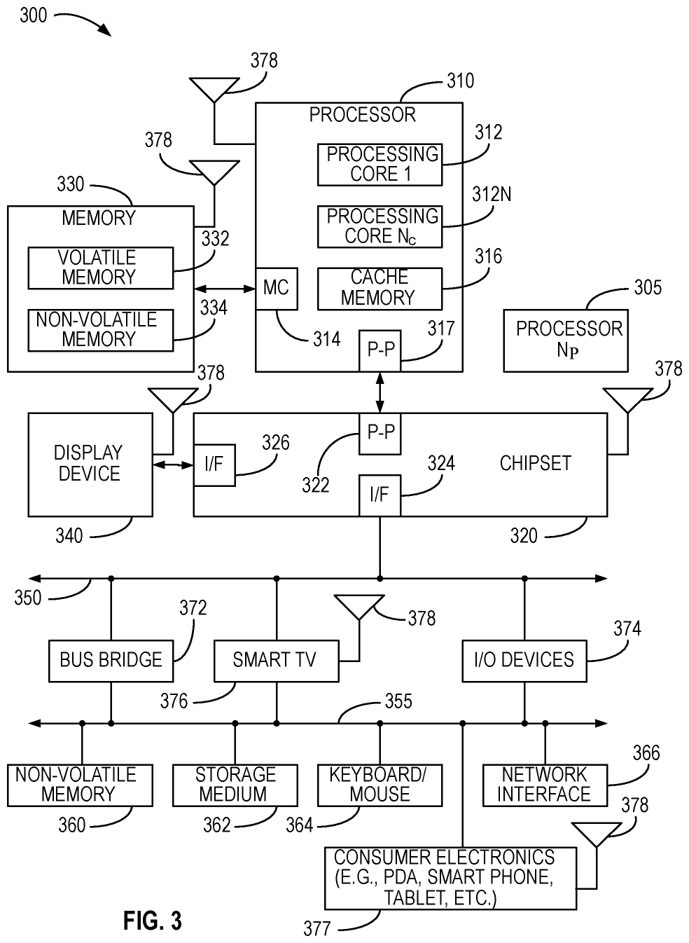

FIG. 3 illustrates a system level diagram, according to one embodiment of the invention. For instance, FIG. 3 depicts an example of an electronic device (e.g., system) including microelectronics package 100 as described herein. FIG. 3 is included to show an example of a higher-level device application for the present invention. In one embodiment, system 300 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 300 is a system on a chip (SOC) system.

In one embodiment, processor 310 has one or more processing cores 312 and 312N, where 312N represents the Nth processor core inside processor 310 where N is a positive integer. In one embodiment, system 300 includes multiple processors including 310 and 305, where processor 305 has logic similar or identical to the logic of processor 310. In some embodiments, processing core 312 includes, but is not limited to, pre-fetch logic to fetch instructions, decode logic to decode the instructions, execution logic to execute instructions and the like. In some embodiments, processor 310 has a cache memory 316 to cache instructions and/or data for system 300. Cache memory 316 may be organized into a hierarchal structure including one or more levels of cache memory.

In some embodiments, processor 310 includes a memory controller 314, which is operable to perform functions that enable the processor 310 to access and communicate with memory 330 that includes a volatile memory 332 and/or a non-volatile memory 334. In some embodiments, processor 310 is coupled with memory 330 and chipset 320. Processor 310 may also be coupled to a wireless antenna 378 to communicate with any device configured to transmit and/or receive wireless signals. In one embodiment, the wireless antenna interface 378 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 332 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 334 includes, but is not limited to, flash memory, phase change memory (PCM), read-only memory (ROM), electrically erasable programmable read-only memory (EEPROM), or any other type of non-volatile memory device.

Memory 330 stores information and instructions to be executed by processor 310. In one embodiment, memory 330 may also store temporary variables or other intermediate information while processor 310 is executing instructions. In the illustrated embodiment, chipset 320 connects with processor 310 via Point-to-Point (PtP or P-P) interfaces 317 and 322. Chipset 320 enables processor 310 to connect to other elements in system 300. In some embodiments of the invention, interfaces 317 and 322 operate in accordance with a PtP communication protocol such as the Intel® QuickPath Interconnect (QPI) or the like. In other embodiments, a different interconnect may be used.

In some embodiments, chipset 320 is operable to communicate with processor 310, 305N, display device 340, and other devices 372, 376, 374, 360, 362, 364, 366, 377, etc. Chipset 320 may also be coupled to a wireless antenna 378 to communicate with any device configured to transmit and/or receive wireless signals.

Chipset 320 connects to display device 340 via interface 326. Display 340 may be, for example, a liquid crystal display (LCD), a plasma display, cathode ray tube (CRT) display, or any other form of visual display device. In some embodiments of the invention, processor 310 and chipset 320 are merged into a single SOC. In addition, chipset 320 connects to one or more buses 350 and 355 that interconnect various elements 374, 360, 362, 364, and 366. Buses 350 and 355 may be interconnected together via a bus bridge 372. In one embodiment, chipset 320 couples with a non-volatile memory 360, a mass storage device(s) 362, a keyboard/mouse 364, and a network interface 366 via interface 324 and/or 304, smart TV 376, consumer electronics 377, etc.

In one embodiment, mass storage device 362 includes, but is not limited to, a solid state drive, a hard disk drive, a universal serial bus flash memory drive, or any other form of computer data storage medium. In one embodiment, network interface 366 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 3 are depicted as separate blocks within the system 300, the functions performed by some of these blocks may be integrated within a single semiconductor circuit or may be implemented using two or more separate integrated circuits. For example, although cache memory 316 is depicted as a separate block within processor 310, cache memory 316 (or selected aspects of 316) can be incorporated into processor core 312.

### Additional Notes

The following, non-limiting examples, detail certain aspects of the present subject matter to solve the challenges and provide the benefits discussed herein, among others.

Example 1 is a microelectronics package comprising: a substrate having a substrate surface; a first die; a solder resist layer connected to the substrate, the solder resist layer defining an opening; a first pad protruding from the substrate surface; and a bridge located at least partially within the opening and in between the first die and the substrate, the bridge comprising a first via that forms a first electrical pathway from the first pad to the first die.

In Example 2, the subject matter of Example 1 optionally includes wherein the bridge is not embedded with the solder resist layer.

In Example 3, the subject matter of any one or more of Examples 1-2 optionally include wherein the bridge is spaced a distance from the substrate surface.

In Example 4, the subject matter of Example 3 optionally includes wherein the distance is from about 5 microns to about 10 microns.

In Example 5, the subject matter of any one or more of Examples 1-4 optionally include wherein the pad is a metal defined pad.

In Example 6, the subject matter of any one or more of Examples 1-5 optionally include a nickel, palladium, gold, or combination thereof layer that circumscribes a portion of the pad.

In Example 7, the subject matter of any one or more of Examples 1-6 optionally include wherein the bridge has a thickness from about 35 microns to about 70 microns.

In Example 8, the subject matter of any one or more of Examples 1-7 optionally include a second pad; and a second die, wherein the bridge including a second via that forms a second electrical pathway from the second pad to the second die.

In Example 9, the subject matter of any one or more of Examples 1-8 optionally include a palladium seed located in between the solder resist layer and the substrate.

In Example 10, the subject matter of any one or more of Examples 1-9 optionally include wherein the first via is a power via.

Example 11 is a microelectronics package comprising: a substrate having a substrate surface; first and second dies; a solder resist layer connected to the substrate, the solder resist layer defining an opening; first and second pads protruding from the substrate surface; a plurality of pillars, a first subset and a second subset of the plurality of pillars extending from the substrate to the first and second dies, respectively; and a bridge located at least partially within the opening and in between the substrate and the first and second dies, the bridge comprising: a first via that forms a first electrical pathway from the first pad to the first die, and a second via that forms a second electrical pathway from the second pad to the second die.

In Example 12, the subject matter of Example 11 optionally includes wherein the bridge is not embedded with the solder resist layer.

In Example 13, the subject matter of any one or more of Examples 11-12 optionally include wherein the bridge is spaced a distance from the substrate surface.

In Example 14, the subject matter of Example 13 optionally includes wherein the distance is from about 5 microns to about 10 microns.

In Example 15, the subject matter of any one or more of Examples 11-14 optionally include wherein the pad is a metal defined pad.

In Example 16, the subject matter of any one or more of Examples 11-15 optionally include a nickel, palladium, gold, or combination thereof layer that circumscribes a portion of the pad.

In Example 17, the subject matter of any one or more of Examples 11-16 optionally include wherein the bridge has a thickness from about 35 microns to about 70 microns.

In Example 18, the subject matter of any one or more of Examples 11-17 optionally include a palladium seed located in between the solder resist layer and the substrate.

In Example 19, the subject matter of any one or more of Examples 11-18 optionally include wherein the first and second vias are power vias.

Example 20 is a method of manufacturing a microelectronics package, the method comprising: forming a substrate comprising a substrate surface; forming pads on the substrate surface; forming a seed layer on the substrate surface; applying a resist layer to the seed layer; forming a cavity in the resist layer to expose a portion of the seed layer; and attaching a bridge to the pads, the bridge located at least partially within the cavity formed by the resist layer.

In Example 21, the subject matter of Example 20 optionally includes attaching a plurality of dies to the bridge.

In Example 22, the subject matter of any one or more of Examples 20-21 optionally include removing a portion of the seed layer located within the cavity formed by the resist layer.

In Example 23, the subject matter of any one or more of Examples 20-22 optionally include flash etching a portion of the seed layer located within the cavity formed by the resist layer.

In Example 24, the subject matter of any one or more of Examples 20-23 optionally include forming vias in the substrate prior to forming the pads.

In Example 25, the subject matter of any one or more of Examples 20-24 optionally include wherein forming the seed layer comprises depositing a palladium material on the substrate surface.

In Example 26, the subject matter of any one or more of Examples 20-25 optionally include wherein forming the seed layer comprises depositing an electroless copper material on the substrate surface.

In Example 27, the subject matter of any one or more of Examples 20-26 optionally include depositing a nickel, palladium, gold, or combination thereof material on the pads.

In Example 28, the subject matter of any one or more of Examples 20-27 optionally include forming pillars extending through the resist layer to a subset of the pads formed on the substrate.

In Example 29, the subject matter of Example 28 optionally includes depositing a nickel, palladium, gold, or combination thereof material on the pads.

In Example 30, the microelectronics packages, systems, apparatuses, or method of any one or any combination of Examples 1-29 can optionally be configured such that all elements or options recited are available to use or select from.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A microelectronics package comprising:
a substrate having a substrate surface;
a first die;
a solder resist layer connected to the substrate, the solder resist layer defining an opening;
a first pad protruding from the substrate surface; and
a bridge located at least partially within the opening and in between the first die and the substrate, the bridge comprising a first via that forms a first electrical pathway from the first pad to the first die.

2. The microelectronics package of claim 1, wherein the bridge is not embedded with the solder resist layer.

3. The microelectronics package of claim 1, wherein the bridge is spaced a distance from the substrate surface.

4. The microelectronics package of claim 3, wherein the distance is from about 5 microns to about 10 microns.

5. The microelectronics package of claim 1, further comprising a nickel, palladium, gold, or combination thereof layer that circumscribes a portion of the pad.

6. The microelectronics package of claim 1, wherein the bridge has a thickness from about 35 microns to about 70 microns.

7. The microelectronics package of claim 1, further comprising:
a second pad; and
a second die,
wherein the bridge including a second via that forms a second electrical pathway from the second pad to the second die.

8. The microelectronics package of claim 1, further comprising a palladium seed located in between the solder resist layer and the substrate.

9. The microelectronics package of claim 1, wherein the first via is a power via.

10. A microelectronics package comprising:
a substrate having a substrate surface;
first and second dies;
a solder resist layer connected to the substrate, the solder resist layer defining an opening;
first and second pads protruding from the substrate surface;
a plurality of pillars, a first subset and a second subset of the plurality of pillars extending from the substrate to the first and second dies, respectively; and
a bridge located at least partially within the opening and in between the substrate and the first and second dies, the bridge comprising:
a first via that forms a first electrical pathway from the first pad to the first die, and
a second via that forms a second electrical pathway from the second pad to the second die.

11. The microelectronics package of claim 10, wherein the bridge is not embedded with the solder resist layer.

12. The microelectronics package of claim 10, wherein the bridge is spaced a distance from the substrate surface.

13. The microelectronics package of claim 10, further comprising a nickel, palladium, gold, or combination thereof layer that circumscribes a portion of the pad.

14. The microelectronics package of claim 10, further comprising a palladium seed located in between the solder resist layer and the substrate.

15. The microelectronics package of claim 10, wherein the first and second vias are power vias.

16. A method of manufacturing a microelectronics package, the method comprising:
forming a substrate comprising a substrate surface;
forming pads on the substrate surface;
forming a seed layer on the substrate surface;
applying a resist layer to the seed layer;
forming a cavity in the resist layer to expose a portion of the seed layer; and
attaching a bridge to the pads, the bridge located at least partially within the cavity formed by the resist layer.

17. The method of claim 16, further comprising attaching a plurality of dies to the bridge.

18. The method of claim 16, further comprising removing a portion of the seed layer located within the cavity formed by the resist layer.

19. The method of claim 16, further comprising flash etching a portion of the seed layer located within the cavity formed by the resist layer.

20. The method of claim 16, further comprising forming vias in the substrate prior to forming the pads.

21. The method of claim 16, wherein forming the seed layer comprises depositing a palladium material on the substrate surface.

22. The method of claim 16, wherein forming the seed layer comprises depositing an electroless copper material on the substrate surface.

23. The method of claim 16, further comprising depositing a nickel, palladium, gold, or combination thereof material on the pads.

24. The method of claim 16, further comprising forming pillars extending through the resist layer to a subset of the pads formed on the substrate.

25. The method of claim 24, further comprising depositing a nickel, palladium, gold, or combination thereof material on the pads.
